(19) United States
(12) Patent Application Publication
(10) Pub. No.: US 2026/0316087 A1
(43) Pub. Date: Oct. 15, 2026

(54) Grinding Container of an Agitator Mill and Agitator Mill with Such a Grinding Container

(71) Applicant: Netzsch-Feinmahltechnik GmbH, Selb (DE)

(72) Inventors: Markus Nichterlein, Marktschorgast (DE); Thomas Goller, Schwarzenbach an der Saale (DE)

(21) Appl. No.: 19/466,644

(22) Filed: Feb. 2, 2026

(30) Foreign Application Priority Data
Feb. 18, 2025 (DE) 10 2025 106 097.5

(51) Int. Cl. B02C 17/16; B02C 17/18

(52) U.S. Cl. CPC B02C 17/16; B02C 17/1815

(57) ABSTRACT

A grinding container of an agitator mill with a grinding container limitation and a cylindrical container jacket having an axial extension and resting against the grinding chamber limitation with an outer jacket and an inner jacket arranged concentrically with the outer jacket, wherein the grinding chamber limitation has a circumferential groove-shaped recess in the region of the inner jacket and a first axial end of the inner jacket can be sunk into the groove-shaped recess in response to temperature-related axial longitudinal expansion as well as an agitator mill with such a grinding container.

### TECHNICAL FIELD

The present invention relates to a grinding container of an agitator mill and an agitator mill with such a grinding container.

### BACKGROUND

Agitator mills serve the purpose of finely and ultra-finely grinding solids in liquids or dry materials. Conventional agitator mills consist of a grinding container, in which an agitator shaft with grinding elements is rotatably mounted. These grinding elements can be formed as fixed disks or striking elements and comminute the grinding material with the help of grinding bodies by means of impact, shearing and frictional forces generated during rotation of the agitator shaft. The mils are used in numerous industries, for example the cement and mineral industry, in the pigment and dye production, in the pharmaceutical industry as well as in the food processing.

In the case of high-temperature applications, for example in the metallurgy or in the case of special processes in the chemical industry, the temperature at which the mill is operated can lie significantly above 100 ˚C, whereby the heat expansion of components plays a critical role. This affects in particular the grinding container, in the case of which temperature differences between an inner jacket and an outer jacket can lead to high mechanical tensions. These tensions are generated because, due to the process heat, the inner container experiences a larger longitudinal expansion than the outer container, which remains cooler. Mechanical tensions, which are critical for the integrity of the entire grinding container and which strongly strain in particular the connection between grinding container and container cover, build up hereby to some extent. In order to counter this, oversized flanges and screw connections are used in conventional agitator mills, which are used in high-temperature applications, in order to catch the occurring tensions. The assembly as well as the disassembly of such mills turns out to be time-intensive and often necessitates the use of special tools.

### SUMMARY

It is thus the object of the present invention to create a possibility for the effective expansion compensation.

According to the invention, this object is in each case solved by the subject matters of the independent claims.

According to a first aspect of the invention, a grinding container of an agitator mill with a grinding chamber limitation and a cylindrical container jacket having an axial extension and resting against the grinding chamber limitation with an outer jacket and an inner jacket arranged concentrically with the outer jacket is provided, wherein the grinding chamber limitation has a circumferential groove-shaped recess in the region of the inner jacket and a first axial end of the inner jacket can be sunk into the groove-shaped recess in response to temperature-related axial longitudinal expansion.

According to a second aspect of the invention, an agitator mill with a grinding container according to the invention is provided.

An idea on which the present invention is based lies in avoiding thermally related longitudinal expansions of the grinding container and the tensions in the grinding container elements resulting therefrom by means of a structural change of the grinding container or of the grinding chamber limitation, respectively, for example of the container cover of the grinding container. Advantageously, a temperature-related longitudinal expansion of the inner jacket in the axial direction is at least partly compensated by means of the design according to the invention in order to reduce or to avoid, respectively, critical mechanical tensions. The groove-shaped recess of the grinding chamber limitation thereby ensures that the free axial end of the inner jacket can expand in response to the occurrence of the temperature-related expansion into the recess in the grinding chamber limitation. The groove-shaped recess thereby allows for an expansion of the inner jacket into the recess until reaching a groove base of the groove-shaped recess counteracts an early contact between inner jacket and grinding chamber limitation. An impingement of the grinding chamber limitation and the occurrence of critical mechanical tensions in the connection between container jacket and grinding chamber limitation is thus avoided. Only when a more extensive longitudinal expansion, which in particular goes beyond the normal level, of the inner jacket, which already rests in the groove base, occurs due to increasing container temperature, the mechanical tensions, which then occur due to the impingement of the grinding chamber limitation, have to be absorbed and compensated by means of the connection between grinding chamber limitation and grinding container, i.e., via a grinding container flange and the connecting means inserted into the latter, for example screw connections. Due to the fact, however, that tensions occur and have to be absorbed in this case, which are reduced as a whole and which are less critical for the integrity of the grinding container, the connection between container jacket and grinding chamber limitation, i.e., especially the grinding container flange, can be embodied so as to be dimensioned smaller. The dimensioning and number of the connecting means can furthermore also be reduced. This has an advantageous effect on the complexity and the weight of the entire agitator mill and reduces the effort during assembly and disassembly.

It is a further idea on which the invention is based to be able to use agitator mills, which are further developed according to the invention, in applications with high operating temperatures, without having to make adaptations to the number and dimensioning of connecting means, such as, for example, flange and screw connections.

Advantageous embodiments and further developments result from the subclaims, which are dependent on the independent claims as well as from the description with reference to the figures.

According to one embodiment, it is provided that an axial depth of the groove-shaped recess is embodied to be larger than an axial longitudinal expansion of the inner jacket within a defined profile of an operating temperature of the agitator mill. The thermally-related axial expansion of the inner jacket can thus be received in the recess, so that said inner jacket only strikes against a fixed limitation only later. The inner jacket thus remains freely movable over almost the defined operating temperature range and jamming between inner jacket and grinding chamber limitation, which are associated with mechanical tensions, are avoided or reduced significantly, respectively. Due to the fact that no or only small force effects occur in the defined temperature range on the container jacket and the grinding chamber limitation thereof due to the expansion of the inner jacket, the stress on the screw connections used for the connection of the individual elements of the grinding container is reduced advantageously, so that said screw connections can be designed and dimensioned to be weaker as a whole. The connections between the individual elements of the grinding container have to thus only be designed to absorb less critical mechanical tensions, which can occur when the longitudinal expansion goes beyond a normal level.

According to a further development, it is provided a radial width of the groove-shaped recess is larger than a wall thickness of the inner jacket. Due to the larger radial width, it is ensured that the inner jacket does not jam radially in the recess, whereby thermally-related restrains and material tensions are advantageously avoided. The inner jacket can thus additionally expand axially in an unhindered manner, without being limited in its movements by a fit, which is too tight.

According to one embodiment, an in particular compressible sealing element is provided, which is inserted in the groove-shaped recess. The sealing element thereby ensures a sealing during the longitudinal expansion of the inner jacket and can be displaced thereby without any damage by means of said inner jacket. The sealing element meanwhile prevents the ingress of grinding material or process media into the groove-shaped recess and thus avoids a contamination or clogging of the expansion chamber. By means of the compressible property, the sealing element can additionally compensate manufacturing tolerances and can ensure a reliable sealing even under varying operating conditions. The sealing element thereby also protects the contact surfaces of the recess and of the inner jacket against abrasive wear due to the ingress of grinding material.

According to a further development, the groove-shaped recess has a circumferential widening for receiving the sealing element. By means of the widening, the sealing element is advantageously held in the groove in a reliable manner, whereby a slipping or detaching during the operation is prevented. The widening is also provided to completely receive the sealing element as soon as the axial end of the inner jacket rests against the groove base of the groove-shaped recess. The targeted reception of the sealing element provides for an improved sealing because it can expand and adapt consistent without exerting excessive pressure on the adjoining components.

According to a further development, the sealing element is formed as sealing ring or as sealing profile with a shape, which essentially corresponds to the groove-shaped recess. An exact fit between sealing element and recess or axial end of the inner jacket, respectively, is attained in an advantageous manner by means of the specific design and the sealing is further improved. The special profiling of the sealing element ensures a reliable sealing against the ingress of grinding material or process media into the expansion chamber and can compensate thermal and mechanical movements as a function of the respective profile shape without losing the sealing effect. The sealing profile can have different designs and can be formed, for example, as lip profile with flexible sealing lip, bead profile with circumferential bead ensuring a consistent contact pressure and improved sealing under pressure or as compressible profile with internal chambering, without limiting the invention thereto. In the last-mentioned embodiment, a hollow chamber arranged internally provides for an elastic deformation in several directions, whereby the sealing element can compensate axial as well as radial movements.

According to one embodiment, a second axial end of the inner jacket lying opposite the first axial end is secured in a stationary manner in the grinding container. By means of the fixation of the second axial end, it is ensured that the temperature-related expansion of the inner jacket takes place only in a defined direction, whereby uncontrolled material tensions are avoided. The freedom of movement of the inner jacket in only an axial direction additionally reduces the necessity of complex guide elements or of additional sealing mechanisms on both axial ends of the grinding container. It goes without saying that both ends of the grinding container can also be provided with corresponding compensation arrangements, whereby a floating mounting of the inner jacket then results.

According to one embodiment, the inner jacket is arranged so as to be radially spaced apart from the outer jacket. By means of the radial distance between inner and outer jacket, the direct heat conduction is decreased advantageously, whereby the outer jacket heats up more slowly and temperature differences between inner and outer container can be compensated better. The air chamber or an optional insulating intermediate layer between the two jackets acts as heat insulation, whereby the outer structure of the mill is protected against excessive heat-up and tension states, which occur in the outer jacket and which are likewise thermally related, are avoided. Due to the fact that the inner jacket can expand independently of the outer jacket, tensions caused by different, even radially thermal expansions between both jackets are thus decreased.

According to a further development, a cooling system arranged between the outer jacket and the inner jacket is provided. The cooling system advantageous provides for a targeted temperature regulation of the inner jacket, whereby a heat-up or overheating beyond a permissible level can be prevented and the thermal stability of the grinding process can be improved. By means of the active cooling, the temperature difference between inner and outer jacket can be decreased, whereby mechanical tensions and material stresses can be minimized.

According to a further development, the cooling system has coolant lines, which run circumferentially, in particular helically, around the inner jacket. By means of the circumferential, in particular helical arrangement of the coolant lines, a large-surface and consistent heat dissipation along the inner jacket can be attained and the temperature gradient can be minimized. By means of the helical guidance, the contact surface between coolant and inner jacket is maximized, whereby the heat dissipation can be improved and the cooling performance can be increased. Together with the design according to the invention of the grinding container, a consistent cooling advantageously contributes to reducing or avoiding, respectively, thermally related material tensions.

According to one embodiment, the outer jacket can be secured to the grinding chamber limitation via a flange connection, in particular can be screwed to the grinding chamber limitation. A stable connection between the outer jacket and the grinding chamber limitation is advantageously established hereby. By means of the embodiment according to the invention of the container jacket, in particular by means of the compensation of the thermal longitudinal expansion of the inner jacket, high tensions in the flange connection are avoided. Oversized flange connections or screw connections, respectively, for the connection thereof to the grinding chamber limitation, in particular the container cover, are thus not required. Due to the fact that external forces do not have to be absorbed by means of heat tensions, screws with smaller diameters and lower strength class can additionally be used. This smaller dimensioning of the screw connections provides for a simpler handling during assembly/disassembly and maintenance, and the use of special tools is not necessary.

According to one embodiment, the container jacket has at least two container sections. The container sections are thereby releasably connected to one another on axial ends facing one another, for example via screw flanges, clamps or other connecting means. By means of the transfer of the longitudinal expansion between the container sections and the targeted compensation on one axial end of the entire grinding container, which is formed from several sections, a thermal expansion of the entire container jacket is made possible while simultaneously avoiding uncontrolled or critical tensions. The setup of the container jacket from several container sections advantageously provides for a modular construction, which can be scaled in length. The targeted transfer of the length expansion thereby allows designing the section joints in a simpler manner, whereby complex expansion joints or elaborate compensation mechanisms between the individual container sections can be forgone.

According to one embodiment, the grinding chamber limitation is formed as grinding container cover. By means of the cover embodiment, the grinding chamber can be opened easily, whereby inspections, maintenance work and cleaning processes are simplified. It goes without saying that grinding chamber limitations with corresponding compensation arrangements can also be provided on both ends of the grinding container.

According to a further development of the agitator mill, the latter is formed as high-temperature range mill. The mill with the design according to the invention of the grinding container is advantageously suitable specifically for applications with high operating temperatures of more than 100 ˚C, in some applications of up to 250 ˚C and more. Due to the targeted longitudinal expansion compensation in the inner jacket, critical mechanical tensions due to heat expansion in an operating temperature range, which is defined for the respective mill, are reduced, whereby tears or deformations are prevented and the structural integrity of the grinding container is maintained.

According to a further development of the agitator mill, a temperature control system, which is integrated in the container jacket, is provided. The temperature control system provides for a precise control of the operating temperature, whereby the grinding process is kept stable and unwanted material changes are avoided. By means of a consistent temperature control, temperature differences between inner and outer jacket are minimized. Mechanical tensions, which occur nonetheless, are reduced or avoided, respectively, by means of the container jacket according to the invention.

Where useful, the above embodiments and further developments can be combined arbitrarily with one another. Further possible embodiments, further developments and implementations of the invention also comprise combinations, which have not been mentioned explicitly, of features of the invention, which have been described above or which will be described below with regard to the exemplary embodiments. The person of skill in the art will thereby in particular also add individual aspects as improvements or additions to the respective basic shape of the present invention.

### BRIEF DESCRIPTION OF THE DRAWINGS

The present invention will be explained in more detail below on the basis of exemplary embodiments with reference to the enclosed figures of the drawings. In the figures:

FIG. 1 shows a schematic illustration of a section of a grinding container according to an exemplary embodiment of the invention;

FIG. 2 shows a lateral sectional illustration of a grinding container section of a grinding container according to an exemplary embodiment of the invention; and

FIG. 3 shows a lateral sectional illustration of an agitator mill according to an exemplary embodiment of the invention.

Elements, features and components, which are identical, functionally identical and which act identically, are in each case provided with the same reference numerals in the figures of the drawing – unless otherwise specified.

Even though specific embodiments and further developments are illustrated and described herein, the person of skill in the art will prefer that a plurality of alternative and/or similar embodiments can replace the illustrated and described specific exemplary embodiments, without turning away from the scope of the present invention. This application is to generally cover all modifications or changes of the specific exemplary embodiments described herein.

The enclosed figures are to provide a further understanding of embodiments of the invention and, in connection with the description, serve the purpose of explaining principles and concepts of the invention. Other exemplary embodiments and many of the mentioned advantages result with regard to the drawings. The drawings are to be understood only as schematic drawings and the elements of the drawings are not necessarily illustrated true to scale to one another. Directional terminology, such as, for instance “top”, “bottom”, “left”, “right”, “above”, “below”, “horizontal”, “vertical”, “front”, “rear” and similar information is used only for explanatory purposes and do not serve to limit the generality to specific designs, as shown in the figures.

Dashed lines in the figures of the drawings clarify that the connections between the components connecting the dashed lines do not mandatorily have physical contact with one another but can likewise be coupled wirelessly with one another.

### DETAILED DESCRIPTION

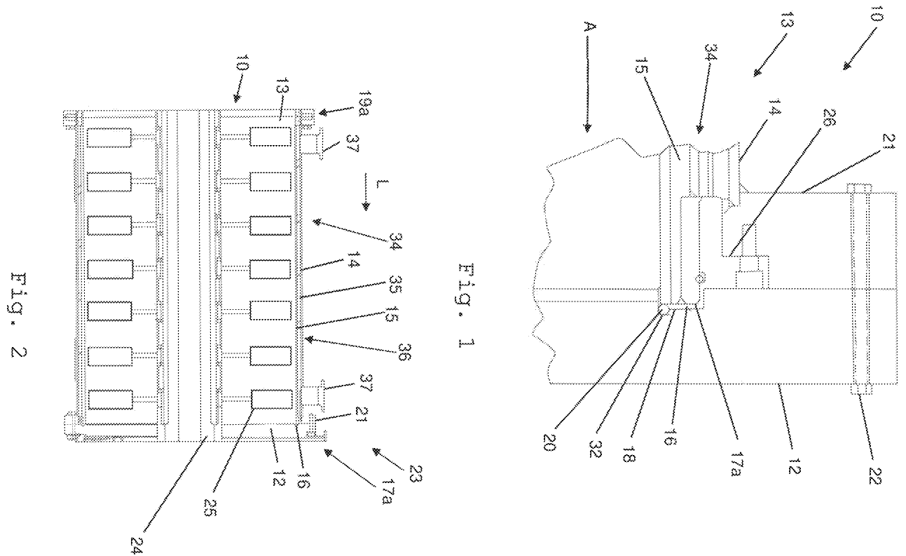

FIG. 1 shows a schematic illustration of a section of a grinding container 10 of an agitator mill 11 according to an exemplary embodiment of the invention. The illustrated section shows the essential components for the compensation of temperature-related longitudinal expansions, for example in a high-temperature agitator mill. The grinding container 10 has an grinding chamber limitation 12, which is formed, for example, in the form of a container cover and which closes the grinding chamber 13 in the axial direction. The grinding chamber limitation 12 is connected to the container jacket 34, which comprises an outer jacket 14 and an inner jacket 15 and which surrounds the grinding chamber 13 and limits the grinding container 10 outwards. An inner jacket 15 , which is in direct contact with the grinding material and which is thus exposed to thermal stresses, is concentrically arranged within the outer jacket 14. The inner jacket 15 can additionally have a wear-reducing coating. The connecting element 26, which concentrically positions the inner jacket 15 and the outer jacket 14 and which is formed in a flange-like manner, is screwed to the grinding container flange 21. The grinding chamber limitation 12 has a circumferential groove-shaped recess 16, into which the first axial end 17a of the inner jacket 15 can be sunk in response to temperature-related longitudinal expansion in the axial direction A. The groove-shaped recess 16 provides for the compensation of longitudinal expansions of the inner jacket 15, which occur within a defined range of the operating temperature. While the grinding process takes place in a high-temperature mill at temperatures above 100 ˚C, the inner jacket 15 expands more strongly due to the process heat than the outer jacket 14, which remains cooler. The groove-shaped recess 16 makes it possible that the first axial end 17a can expand into the recess 16 until reaching the groove base 18 of the recess 16, without impinging the grinding chamber limitation 12 and without thereby generating critical tensions in the connection between container jacket 34 and grinding chamber limitation 12. When a more extensive longitudinal expansion occurs due to increasing container temperature, in particular beyond the defined operating temperature range, the tensions occurring as a result are absorbed by means of the connection between grinding chamber limitation 12 and grinding container 10 or container jacket 34, respectively, i.e., via the grinding container flange 21 and the screw connections 22 inserted therein. Due to the fact, however, that tensions, which are decreased as a whole, have to be absorbed in this case, the grinding container flange 21 can be dimensioned to be smaller. The dimensioning and number of screw connections 22 can furthermore also be reduced. The grinding chamber limitation 12, in the exemplary embodiment a container cover attached to the grinding container 10, thus provides an expansion chamber, into which the inner jacket 15 can penetrate up to a certain level in response to longitudinal expansion, without contacting the grinding chamber limitation 12 and without generating mechanical tensions.

The second axial end 19a of the inner jacket 15, which is not shown in FIG. 1, is fixed in a stationary manner in the grinding container 10. The entire longitudinal expansion is thus discharged axially only in the direction of the groove-shaped recess 16 and is compensated there up to a certain expansion level. A sealing element 20 inserted into the groove-shaped recess 16 ensures a reliable sealing between the grinding chamber limitation 12 and the first axial end 17a of the inner jacket 15 before and during the longitudinal expansion. The sealing element 20 prevents the ingress of grinding material or process media into the groove-shaped recess 16 and simultaneously protects the contact surfaces against wear and contamination. The sealing element 20 is formed in an elastic manner, for example as sealing ring or sealing profile, and can be compressed by means of the first axial end 17a of the inner jacket 15 in response to the longitudinal expansion thereof, whereby the sealing element 20 can escape into the widening 32 of the recess 16 in the course of the longitudinal expansion. As soon as the first axial end 17a of the inner jacket reaches the groove base 18, the sealing element 20 is pushed completely into the widening and can thus not be squeezed through the inner jacket 15 and be damaged irreversibly. The widening 32 does not only serve as escape space for the sealing element 20 impinged by the inner jacket 12 but also effects a position fixation of the sealing element 20 and prevents the latter from falling out. Before and during the longitudinal expansion of the inner jacket 15 until reaching the groove base 18, the groove-shaped recess 16 is sealed by the sealing element 20 with respect to the grinding chamber 13. The grinding container flange 21, via which the container jacket 34 is fastened to the grinding chamber limitation 12, serves for the stable fixation of the components. Due to the design according to the invention for receiving the longitudinal expansion of the inner jacket 15, reduced mechanical tensions occur in the grinding container flange 21, so that the screw connections 22 and the grinding container flange 21 itself can be dimensioned more weakly than in conventional agitator mills 11 without expansion compensation. The number of screw connections 22 at the circumference of the grinding container flange 21 can also be reduced.

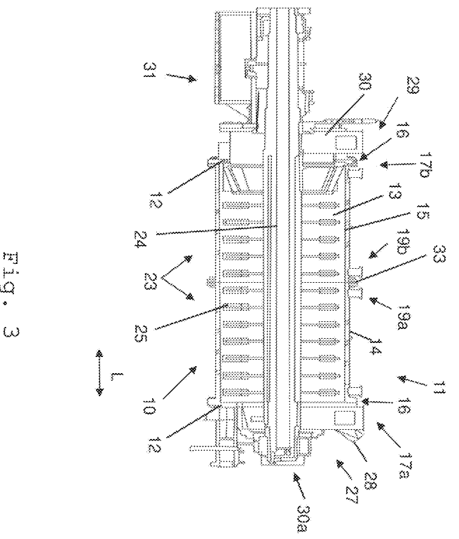

FIG. 2 shows a lateral sectional illustration of a grinding container section 23 of a grinding container 10 according to an exemplary embodiment of the invention. Embodiments are possible, in the case of which the grinding container 10 is formed from only one grinding container section 23, which is embodied as illustrated here. FIG. 2 shows the setup of the grinding container 10 in part, in particular the arrangement of the inner jacket 15 within the outer jacket 14 as well as the option of a one-sided axial longitudinal expansion of the inner jacket 15 or the compensation thereof, respectively. The inner jacket 15 is concentrically arranged within the outer jacket 14 and extends over the entire axial length L of the grinding container 10. The inner jacket 15 is fixed in a stationary manner on a second axial end 19a, while the opposite first axial end 17a can be lowered into the circumferential groove-shaped recess 16 of the grinding chamber limitation 12. A directed compensation of the axial longitudinal expansion of the inner jacket 15 is thus made possible. The container jacket 34 is screwed to the grinding chamber limitation 12 via the container flange 21. An agitator shaft 24, which is provided with several agitator elements 25, is rotatably mounted within the grinding container 10. Grinding bodies (not illustrated) introduced into the grinding container 10 are moved in the grinding chamber 13 by means of the rotation of the agitator shaft 24 and a fine or ultrafine grinding of the grinding material is carried out by means of the acting impact, shearing and frictional forces. The outer jacket 14 is arranged spaced apart from the inner jacket 15. In the resulting intermediate space 35, a cooling system 36 is provided in the exemplary embodiment, in which a coolant pumped through both nozzles 37 circulates around the container jacket 34 in the intermediate space 35 and discharges resulting process heat.

FIG. 3 shows a lateral sectional illustration of an agitator mill 11 according to an exemplary embodiment of the invention. The modular setup of the grinding container 10, i.e., the formation thereof from two connected grinding container sections 23, is illustrated in FIG. 3. The individual grinding container sections 23 each have the setup, which has already been described in connection with FIG. 2. The design of the grinding container limitations 12 described in connection with FIG. 1 for the compensation of the longitudinal expansion of the axial ends 17a, b of the respective grinding container sections 23 in groove-shaped recesses 16 is in each case provided on both ends 27, 29 of the grinding container 10. The axial ends 19a, b lying centrally in the grinding container 10 are connected to one another via radially protruding connecting flanges 33 and are secured in a stationary manner in the grinding container 10. An agitator shaft 24, which is fitted with several agitating elements 25, extends over the entire axial length L of the grinding container 10 in the agitator mill 11. The agitating elements 25 are arranged in such a way that they comminute the grinding material in the grinding container 10 with the help of the grinding bodies (not illustrated) located in the grinding chamber 13 by means of the rotation of the agitator shaft 24. An inlet housing 28, through which the grinding material is introduced into the grinding container 10, is arranged on the end 27 of the agitator mill 11, which is on the right in FIG. 3. An outlet housing 30, via which the ground product leaves the grinding container 10, is located on the opposite end 29, which is on the left in FIG. 3. The agitator shaft 24 is supported via at least one further bearing and is guided in a stable manner in the grinding container 10. The embodiment of the grinding container 10 illustrated in FIG. 3 allows for a scalable construction of the agitator mill 11 by adding further grinding container sections 23 in response to compensation of the temperature- related longitudinal expansion of the entire inner jacket 15 in the respective grinding container sections 23. In the case of the arrangement of more than two grinding container sections 23, which is not illustrated in FIG. 3, the expansion compensation in the further grinding container sections 23 takes place, for example, by providing groove-shaped recess 16 in connecting flanges of the further grinding container sections 23.

Different features have been combined in the preceding detailed description in order to improve the stringency of the illustration in one or several examples. It should be clear thereby, however, that the above description is only of an illustrative, but in no way of a limiting nature. It serves to cover all alternatives, modifications and equivalents of the different features and exemplary embodiments. Many other examples will be clear immediately and directly to the person of skill in the art based on his expert knowledge in consideration of the above description.

The exemplary embodiments have been selected and described in order to be able to illustrate the principles on which the invention is based and its applications in practice in the best possible way. Persons of skill in the art can thus optimally modify and use the invention and its different exemplary embodiments with regard to the intended purpose. The terms “including” and “having” are used as neutral terminology for the corresponding terms “comprising” in the claims as well as the description. A use of the terms “a” and “an” is to furthermore not generally rule out a plurality of features and components described in this way.

1. A grinding container of an agitator mill with a grinding container limitation and a cylindrical container jacket having an axial extension resting against the grinding chamber limitation with an outer jacket and an inner jacket arranged concentrically with the outer jacket, wherein the grinding chamber limitation has a circumferential groove-shaped recess in the region of the inner jacket and a first axial end of the inner jacket can be sunk into the groove-shaped recess in response to temperature-related axial longitudinal expansion.

2. The grinding container according to claim 1, wherein an axial depth of the groove-shaped recess is larger than an axial longitudinal expansion of the inner jacket within a defined profile of an operating temperature of the agitator mill.

3. The grinding container according to claim 1, wherein a radial width of the groove-shaped recess is larger than a wall thickness of the inner jacket.

4. The grinding container according to claim 1, wherein an in particular compressible sealing element is provided, which is inserted in the groove-shaped recess.

5. The grinding container according to claim 4, wherein the groove-shaped recess has a circumferential widening for receiving the sealing element.

6. The grinding container according to claim 4, wherein the sealing element is formed as sealing ring or as sealing profile with a shape, which essentially corresponds to the groove-shaped recess.

7. The grinding container according to claim 1, wherein a second axial end of the inner jacket lying opposite the first axial end is secured in a stationary manner in the grinding container.

8. The grinding container according to claim 1, wherein the inner jacket is arranged so as to be radially spaced apart from the outer jacket.

9. The grinding container according to claim 1, wherein a cooling system arranged between the outer jacket and the inner jacket is provided.

10. The grinding container according to claim 9, wherein the cooling system has coolant lines, which run in particular helically around the inner jacket.

11. The grinding container according to claim 1, wherein the container jacket can be secured to the grinding chamber limitation in particular via a flange connection, in particular can be screwed to the grinding chamber limitation.

12. The grinding container according to claim 1, wherein the container jacket is formed from at least two container sections.

13. The grinding container according to claim 1, wherein the grinding chamber limitation is formed as grinding container cover.

14. An agitator mill with a grinding container having a grinding container limitation and a cylindrical container jacket having an axial extension resting against the grinding chamber limitation with an outer jacket and an inner jacket arranged concentrically with the outer jacket, wherein the grinding chamber limitation has a circumferential groove-shaped recess in the region of the inner jacket and a first axial end of the inner jacket can be sunk into the groove-shaped recess in response to temperature-related axial longitudinal expansion.

15. The agitator mill according to claim 14, wherein the agitator mill is formed as high-temperature range mill.

16. The agitator mill according to claim 14, wherein a temperature control system integrated in the container jacket is provided.

17. The grinding container according to claim 2, wherein a radial width of the groove-shaped recess is larger than a wall thickness of the inner jacket.

18. The grinding container according to claim 2, wherein an in particular compressible sealing element is provided, which is inserted in the groove-shaped recess.

19. The grinding container according to claim 2, wherein a second axial end of the inner jacket lying opposite the first axial end is secured in a stationary manner in the grinding container.

20. The grinding container according to claim 5, wherein the sealing element is formed as sealing ring or as sealing profile with a shape, which essentially corresponds to the groove-shaped recess.
